(19) United States
(12) Patent Application Publication
(10) Pub. No.: US 2024/0258593 A1
(43) Pub. Date: Aug. 1, 2024

(54) SYSTEM AND METHOD FOR MEASURING LITHIUM-ION STATE-OF-CHARGE

(71) Applicant: HELLA GMBH & CO. KGAA, Lippstadt (DE)

(72) Inventor: Brian James Stockford, South Lyon, MI (US)

(21) Appl. No.: 18/290,423

(22) PCT Filed: Jun. 1, 2022
(86) PCT No.: PCT/EP2022/064845

§ 371 Date: Nov. 13, 2023

Related U.S. Application Data
(60) Provisional application No. 63/212,141, filed on Jun. 18, 2021.

(51) Int. Cl. H01M 10/48; G01R 31/367; G01R 31/382

(52) U.S. Cl. CPC H01M 10/48; G01R 31/382; G01R 31/367

(57) ABSTRACT

A system and a method for measuring a state-of-charge of a lithium-ion battery are provided. The system and the method include first and second capacitive electrodes that are applied to the exterior of a pouch-type battery cell or a battery stack, the capacitive electrodes defining a capacitive coupling. The system and method further include measuring the capacitance of the capacitive coupling and correlating the capacitance with a state-of-charge of the lithium-ion battery. The capacitively-derived state-of-charge measurement can be used in combination with a voltage-derived state-of-charge measurement, thereby providing a redundant state-of-charge determination. Other applications include low battery warnings and end-of-life warnings.

### CROSS-REFERENCE TO RELATED APPLICATIONS

This application claims the benefit of U.S. Provisional Application 63/212,141, filed Jun. 18, 2021, which is hereby incorporated by reference in its entirety.

### FIELD OF THE INVENTION

The present invention relates to a system and a method for measuring the state-of-charge of a lithium-ion battery.

### BACKGROUND OF THE INVENTION

Pouch-type lithium-ion batteries have gained widespread use for plug-in hybrid and electric vehicles. Pouch-type lithium-ion batteries generally include a cathode opposite an anode, with a separator therebetween. The cathode can include lithium and a metal oxide, and the anode can include graphite or amorphous carbon. The cathode, anode, and separator are often laminated in a stack structure contained within a sealed pouch. The sealed pouch contains a liquid electrolyte for conducting lithium ions between the anode and the cathode.

When the lithium-ion battery is discharging, lithium ions are extracted from the anode and inserted into the cathode. When the lithium-ion battery is charging, lithium ions are extracted from the cathode and inserted into the anode. However, lithium-ion batteries swell or expand during the charging cycle due to gas generation, which can be problematic if the battery is overcharged. Conversely, when discharging, lithium-ion batteries contract. While this change in volume during charging cycles is known, there remains a continued need for systems and methods that monitor lithium-ion batteries during charging cycles for automotive and other applications.

### SUMMARY OF THE INVENTION

A system and a method for measuring a state-of-charge of a lithium-ion battery are provided. The system and the method include first and second capacitive electrodes that are applied to a pouch-type battery cell or a battery stack, the capacitive electrodes defining a capacitive coupling. The system and method further include measuring the capacitance of the capacitive coupling and correlating the capacitance with a state-of-charge of the lithium-ion battery. The capacitively-derived state-of-charge measurements can be used in combination with voltage-derived state-of-charge measurements, thereby providing a redundant state-of-charge determination. Other applications include low battery warnings and end-of-life warnings.

In one embodiment, the system includes a battery stack having first and second isolator plates at opposing ends of the battery stack, the battery stack having a plurality of battery cells. The first and second capacitive electrodes are moveable with the first and second isolator plates, respectively. The system further includes a spring element disposed between the first isolator plate and the second isolator plate, the spring element being an extension spring that resists outward movement of the first and second isolator plates. In this regard, the battery stack is held in compression between the first and second isolator plates by operation of the spring element, thereby preventing rupture of the external battery pouch.

In another embodiment, the method includes measuring a capacitive coupling of the first and second capacitive electrodes during charging or discharging of the battery cells. The method further includes determining a state-of-charge percentage of the battery cells based on the measured capacitive coupling of the first and second electrodes. Determining a state-of-charge percentage based on a capacitive coupling is performed by formula in digital logic or with reference to a look-up table stored in memory. The method further includes controlling the charging or discharging of the battery cell based on the determined state-of-charge.

These and other features and advantages of the present invention will become apparent from the following description of the invention, when viewed in accordance with the accompanying drawings and the appended claims. It will be appreciated that any of the preferred and/or optional features of the invention may be incorporated alone, or in appropriate combination, within embodiments of the invention, while still falling within the scope of claim 1, even if such combinations are not explicitly claimed in the appended claims.

### BRIEF DESCRIPTION OF THE DRAWINGS

FIG. 1 illustrates a battery cell including a capacitive sensor for measuring state-of-charge.

FIG. 2 illustrates a battery module including multiple battery cells and a capacitive sensor for measuring state-of-charge.

FIG. 3 is a circuit diagram illustrating a measurement circuit for determining a capacitance and correlating the capacitance with a state-of-charge.

FIG. 4 is a flow diagram illustrating a system for determining a capacitance of capacitive electrodes joined to a battery cell or a battery stack.

FIG. 5 includes a look-up table illustrating state-of-charge as a function of the percentage expansion of a battery cell.

### DETAILED DESCRIPTION OF THE PRESENT EMBODIMENTS

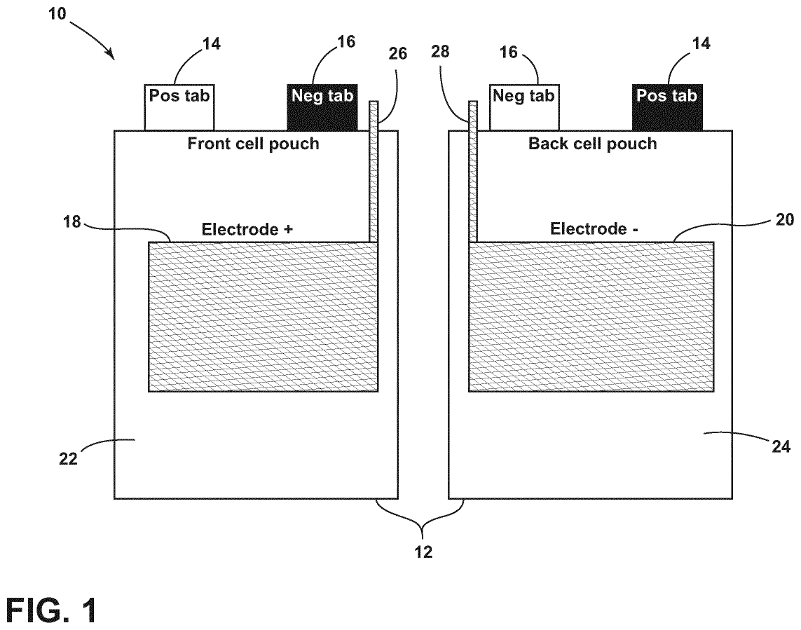

A system for measuring a state-of-charge of a battery is generally illustrated in FIG. 1. The system includes a lithium-ion battery 10 having a battery pouch 12 that forms a gas-tight enclosure around a cathode, an anode, and a separator. The cathode, anode, and separator generally comprise a laminated structure within a liquid electrolyte. The separator prevents a short circuit between the cathode and the anode and allows only lithium ions to pass through, optionally comprising polypropylene film or polyethylene film. The lithium-ion battery 10 includes a liquid electrolyte, for example LIBF₄ or LIBF₆, which acts as a carrier of lithium ions. A positive tab 14 protrudes from the battery pouch 12 and is electrically connected to the cathode, and a negative tab 16 protrudes from the battery pouch 12 and is electrically connected to the anode. First and second capacitive electrodes 18, 20 are applied to opposing exterior surfaces 22, 24 of the battery pouch 12, the capacitive electrodes 18, 20 defining a capacitive coupling. A first electrical lead 26 extends from the first capacitive electrode 18, and a second electrical lead 28 extends from the second capacitive electrode 20. The capacitive electrodes 18, 20 are spaced apart from each other by the front-to-back thickness of the battery pouch 12. As the battery pouch swells, this distance increases, and as the battery pouch contracts, this distance decreases.

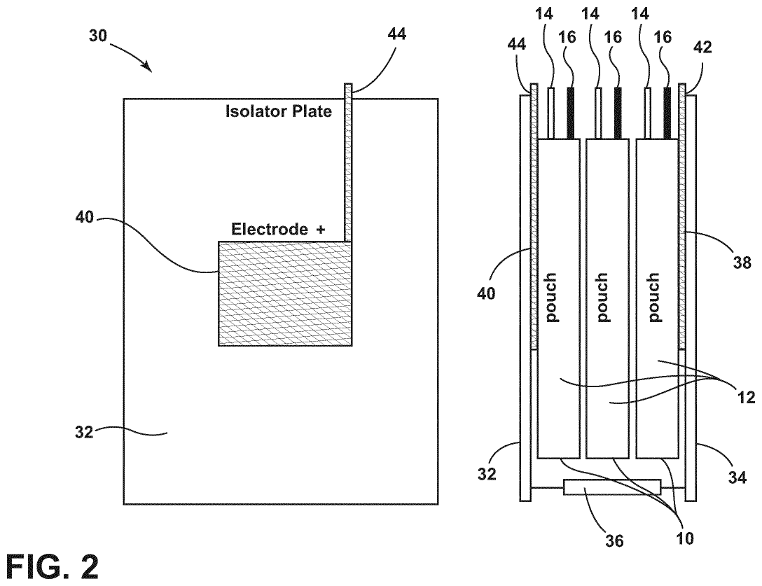

As alternatively shown in FIG. 2, a battery module 30 includes multiple pouch-type battery cells 10 arranged in a battery stack. Each battery cell 10 includes a battery pouch 12 that sealably encloses a cathode, an anode, and a separator. In addition, positive and negative battery tabs or terminals 14, 16 protrude from each battery pouch 12. First and second isolator plates 32, 34 are disposed on opposing ends of the battery stack, sandwiching the battery stack therebetween. As the battery pouches swell, the distance between the isolator plates 32, 34 increases, and as the battery pouches contract, this distance decreases. A spring element 36 is connected to the first and second isolator plates 32, 34. The spring element 36 is optionally an extension spring. The spring element 36 is adapted to resist outward movement of the first and second isolator plates 32, 34 and holds the battery stack in compression between the first and second isolator plates 32, 34. First and second capacitive electrodes 38, 40 are applied to respective first and second isolator plates 32, 34, the capacitive electrodes 38, 40 defining a capacitive coupling. A first electrical lead 42 extends from the first capacitive electrode 38, and a second electrical lead 44 extends from the second capacitive electrode 40. The capacitive electrodes 38, 40 are applied to an interior-facing surface of the isolator plates 32, 34 in the illustrated embodiment, but can be applied to an exterior-facing surface of the isolator plates 32, 34 in other embodiments. The capacitive electrodes 38, 40 are spaced apart from each other by the front-to-back thickness of the battery stack. As each battery pouch swells, this distance increases, and as each battery pouch contracts, this distance decreases.

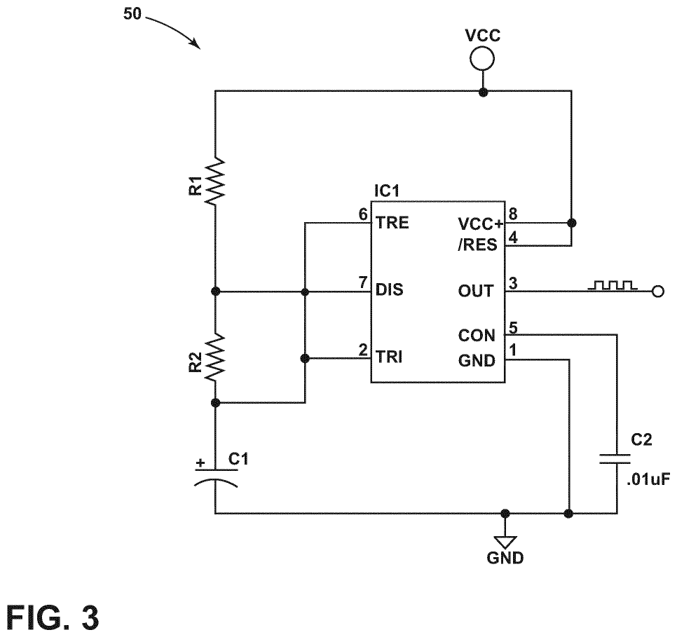

As shown in FIG. 3, a capacitive sensing circuit measures the capacitive coupling between the first and second capacitive electrodes 38, 40 as an indirect measure of the distance between the first and second capacitive electrodes. The capacitive sensing circuit can include essentially any circuitry for measurement capacitance, including analog circuitry, digital circuitry, or analog and digital circuitry. For example, the capacitive sensing circuit can include an integrated circuit for measuring the RC time constant, that is, the time for charging the capacitive electrodes to 63.2% of a charging voltage (e.g., 5V) through a known resistance. As shown in FIG. 3 for example, a timer circuit IC1 is used to measure the capacitive coupling between the first and second capacitive electrodes 38, 40 with nano-Farad resolution. More specifically, the timer circuit IC1 produces an output pulse 3 whose duration is determined by the value of R1 and C1, with C1 being the capacitance of the two electrodes 38, 40. In use, a trigger pulse is applied to the input terminal 2, which begins the output pulse 3 (high). When the charge across C1 reaches ⅔ of VCC, the output returns to low, marking the end of the pulse (low). By dividing the duration of the pulse by 1.1 times the value of R1, the value of C1 is determined. The integrated circuit of FIG. 3 is one example of a capacitive sensing circuit, however, other capacitive sensing circuits can be used in other embodiments. As another example, the capacitive sensing circuit can include an FDC1004 integrated circuit from Texas Instruments, which includes a capacitance-to-digital converter. Still other sensing circuits can be used in other embodiments.

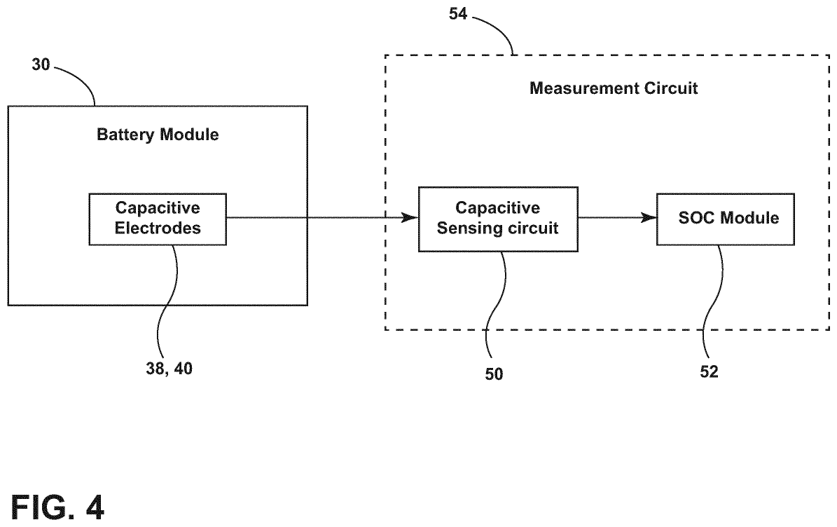

As shown in FIG. 4, the output of the capacitive sensing circuit 50 is received by a state-of-charge module 52 for determining a state-of-charge percentage of the battery module 30. The capacitive sensing circuit 50 and the state-of-charge module 52 collectively comprise a measurement circuit 54, which can comprise digital logic on an integrated circuit. The state-of-charge module 52 includes machine-readable instructions that, when executed, cause the state-of-charge module 52 to (a) convert the capacitance of the capacitively-coupled electrodes into an indirect measure of the percent expansion (or contraction) of the battery pouch(es) and (b) convert the percent expansion (or contraction) of the battery pouch(es) into a state-of-charge percentage.

With respect to function (a), the distance d between the capacitive electrodes 38, 40 is determined in digital logic by dividing the product of the dielectric constant k (which is known or approximated) and the area A of the electrodes 38, 40 (which is known or approximated) by the capacitance C (which is determined by the capacitive sensor circuit 50) according to the following formula: d=(κA)/C. With respect to function (b), the state-of-charge percentage or SOC can be determined by formula or with reference to a look-up table stored in memory. For example, the distance separating the first and second electrodes d is used to calculate the percent expansion PE according to the equation PE=d/D−1, where D is the nominal distance separating the first and second electrodes. A negative percent expansion PE indicates a contraction of the battery pouch, and a positive percent expansion PE indicates an expansion of the battery pouch. For example, a distance d of 8 mm and a nominal distance D of 10 mm indicates a percent expansion of −0.2, while a distance d of 12 mm and a nominal distance D of 10 mm indicates a percent expansion of 0.2.

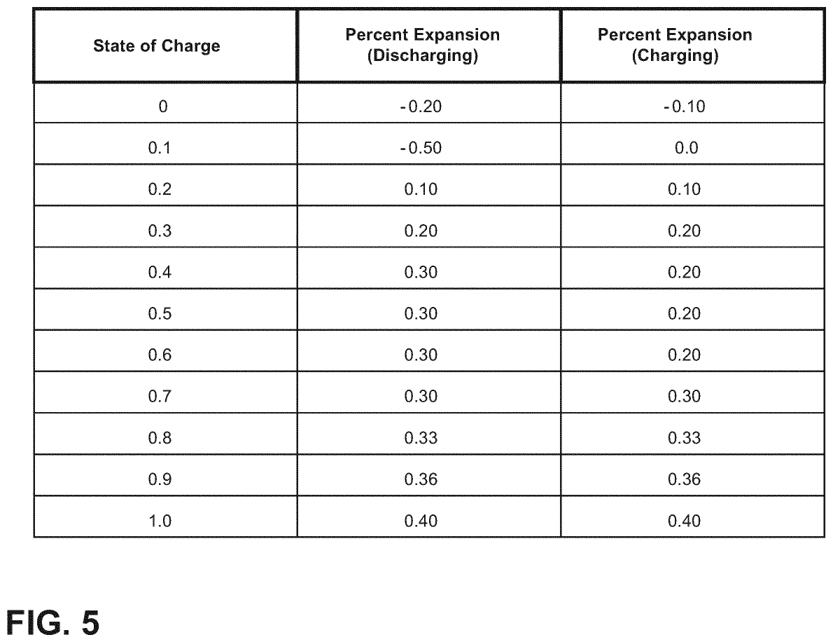

The SOC can be determined from the percent expansion PE by interpolation using a look-up table stored in memory, for example the look-up table shown in FIG. 5. As shown in FIG. 5, a strong correlation was found to exist between the percent expansion of a lithium-ion battery pouch and the SOC of the lithium-ion battery pouch, particularly below 30% SOC and above 70% SOC. Below 30% SOC, the total percent expansion of the battery pouch decreases approximately linearly from 0.2 to −0.2 of the nominal battery pouch thickness as the SOC decreased from 30% to zero. Above 70% SOC, the total percent expansion of the battery pouch increased approximately linearly by 0.3 to 0.4 of the nominal battery pouch thickness as the SOC increased from 70% to 100%. Between 30% and 70% SOC, the percent expansion of the battery pouch was relatively constant at 0.2 to 0.3 of the nominal battery pouch thickness. The relationship between SOC and percent expansion was relatively uniform for both charging and discharging cycles. Alternatively, the SOC can be determined by formula as follows, which is non-limiting:

$$\\ if PE < 0.2 , SOC = 0.16 \cdot PE + 0.13$$

$$\\ if 0.2 \leq PE \leq 0.3 , SOC = 0.3 to 0.7$$

$$\\ if 0.3 < PE , SOC = 2.8 \cdot PE - 0.1$$

The output of the state-of-charge module 52 can also be used in functional safety applications, optionally as a redundant low state-of-charge diagnostic circuit. For example, the measurement circuit 54 can cause an alarm to be generated if the SOC (as calculated by look-up table or formula) decreases to less than 30%. In addition or alternatively, the output of the state-of-charge module 52 can be used to generate a low battery warning, optionally in response to the percent expansion falling below a threshold value, for example a PE of less than 0.2. The output of the state-of-charge module 52 can be used to generate an end-of-life warning, particularly if a departure is detected between capacitively-derived SOC measurements and voltage-derived SOC measurements. For example, if voltage-derived SOC measurements are less than 80% of capacitively-derived SOC measurements, the measurement circuit 54 can cause an end-of-life warning to be generated, signaling a replacement of the battery is needed.

Though described above in connection with capacitive sensing, the present invention can also include other indirect measurements of the expansion of the battery pouch, including inductive sensing and ultrasonic sensing. For example, the present invention can include measuring an inductive coupling between first and second inductive elements that are movable with the isolator plates. Further by example, the present invention can include time-of-flight ultrasonic sensors to measure the distance between isolator plates with mm precision. The output of these sensors can be coupled to the state-of-charge module as set forth above for providing a redundant state-of-charge measurement, end-of-life warning, or other applications.

The above description is that of current embodiment of the invention. Various alterations and changes can be made without departing from the spirit and broader aspects of the invention. This disclosure is presented for illustrative purposes and should not be interpreted as an exhaustive description of all embodiments of the invention or to limit the scope of the claims to the specific elements illustrated or described in connection with these embodiments. Any reference to elements in the singular, for example, using the articles “a,” “an,” “the,” or “said,” is not to be construed as limiting the element to the singular.

1. An electrical system comprising:
a battery stack comprising a plurality of lithium-ion battery cells, each of the plurality of lithium-ion battery cells including a battery pouch that sealably encloses a cathode, an anode, and a separator, the separator being disposed between the cathode and the anode;
first and second isolator plates disposed on opposing ends of the battery stack, wherein expansion of the plurality of lithium-ion battery cells causes the first and second isolator plates to move outwardly relative to each other; and
first and second capacitive electrodes that are movable with the first and second isolator plates, respectively, such that the first and second capacitive electrodes define a capacitance that varies during discharging and recharging of the plurality of lithium-ion battery cells.

2. The system of claim 1 further including a measurement circuit coupled to the first and second capacitive electrodes, the measurement circuit being adapted to (a) measure the capacitance of the first and second capacitive electrodes and (b) determine a state-of-charge percentage of the battery stack based on the measured capacitance of the first and second capacitive electrodes.

3. The system of claim 1 further including a spring element disposed between the first isolator plate and the second isolator plate.

4. The system of claim 3 wherein the spring element comprises an extension spring that resists outward movement of the first and second isolator plates.

5. The system of claim 3 wherein the battery stack is held in compression between the first isolator plate and the second isolator plate by the spring element.

6. A method for measuring the state-of-charge of a lithium-ion battery cell including a battery pouch that sealably encloses a cathode, an anode, and a separator, the method comprising:
providing first and second capacitive electrodes that are movable in response to expansion of the battery cell;
measuring a capacitive coupling of the first and second capacitive electrodes during charging or discharging of the battery cell; and
determining a state-of-charge percentage of the battery cell based on the measured capacitive coupling of the first and second electrodes.

7. The method of claim 6 wherein the battery cell forms part of a battery stack comprising a plurality of battery cells.

8. The method of claim 7 further including positioning first and second isolator plates on opposing end portions of the battery stack.

9. The method of claim 8 further including biasing the first isolator plate and the second isolator toward each other with a spring force.

10. The method of claim 6 further including controlling the charging or discharging of the battery cell based on the determined state-of-charge percentage of the battery cell.

11. An electrical system comprising:
a battery cell including a battery pouch that sealably encloses a cathode, an anode, and a separator, the separator being disposed between the cathode and the anode;
first and second capacitive electrodes joined to first and second exterior surfaces of the battery cell, the first and second capacitive electrodes defining a capacitive coupling; and
a measurement circuit coupled to the first and second capacitive electrodes, the measurement circuit being adapted to (a) measure the capacitive coupling of the first and second capacitive electrodes during discharging or recharging of the battery cell and (b) determine a state-of-charge percentage of the battery cell based on the measured capacitive coupling of the first and second capacitive electrodes.

12. The system of claim 11 wherein the battery pouch forms a gas-tight enclosure around the cathode, the anode, and the separator.

13. The system of claim 11 wherein the first and second capacitive electrodes comprise conductive substrates that are adhered to the first and second exterior surfaces of the battery cell.

14. The system of claim 11 wherein the measurement circuit includes a capacitive sensing circuit for measuring the capacitive coupling.

15. The system of claim 14 wherein the measurement circuit includes a state-of-charge module for determining the state-of-charge percentage based on a look-up table stored to memory.
